(19) United States
(12) Patent Application Publication
(10) Pub. No.: US 2024/0348207 A1
(43) Pub. Date: Oct. 17, 2024

(54) INTEGRATED CIRCUIT COMPRISING A CURRENT SOURCE OF MODULATED INTENSITY AND CORRESPONDING GENERATION METHOD

(71) Applicant: STMicroelectronics International N.V., Geneva (CH)

(72) Inventors: Philippe LE FEVRE, Aix En Provence (FR); Arnaud GAMET, Pourrières (FR); Estelle DANY, GINASSERVIS (FR)

(21) Appl. No.: 18/624,627

(22) Filed: Apr. 2, 2024

(30) Foreign Application Priority Data
Apr. 17, 2023 (FR) 2303819

(51) Int. Cl. H03F 1/02; H03F 3/45

(52) U.S. Cl. CPC H03F 1/0222; H03F 3/45273; H03F 2200/66

(57) ABSTRACT

The integrated circuit comprises a current source configured to generate a control current whose intensity is modulated by an input signal. The current source includes a first stage configured to autonomously generate a constant component of the control current, and a second stage configured to autonomously generate a control current component that is modulated by the input signal.

### CROSS REFERENCE TO RELATED APPLICATIONS

This application claims the priority benefit of French patent application number 2303819, filed on Apr. 17, 2023, entitled “Circuit Integre Comprenant Une Source De Courant D'intensite Modulee Et Procede De Generation Correspondant,” which is hereby incorporated by reference to the maximum extent allowable by law.

### TECHNICAL FIELD

The embodiments and implementations of the present disclosure relate to integrated circuits, in particular to the generation a current, the intensity whereof is modulated by a signal, in particular in a feedback loop of a controlled system.

### BACKGROUND

A controlled system is typically intended to generate an output signal that provides feedback on its generation, via a feedback loop.

The feedback loop can generate a feedback signal of a different kind to the output signal. For example, the output signal controlled by the feedback loop can be the average value of the amplitude of a voltage oscillator signal, or the voltage level of a potential point; whereas the feedback signal can, for example, be carried by a control current.

Moreover, a variable that is not generated by the system can control the system, for example a temperature measurement can control a system generating an output signal of any kind. The control current can be generated as a function of temperature to control the output signal.

Independently of the controlled system, the generation of control currents, in particular in feedback loops, presents difficulties insofar as current generator circuits are typically based on an architecture of the β-multiplier (“beta multiplier”) type, as illustrated for example in FIG. 1.

FIG. 1 illustrates a classic example of a current generator circuit IGEN_0 of the self-regulating β-multiplier type with an attenuation loop ATLP_0, typically used for the feedback of a system generating an AC signal Vin_0.

The feedback uses a non-linearity in the design providing a clipping effect RECT_0 and a low-pass filter LPF_0 to generate an output current Iout_0, the intensity whereof varies inversely to the average value of the amplitude of the input signal Vin (by the clipping effect RECT_0 to isolate the amplitude and by the filter effect LPF_0 to obtain an average).

The drawbacks of this type of circuit IGEN_0 are that the feedback gain is strongly dependent on the value of the DC component of the output current Iout_0, and that it is difficult, if not impossible, to trim one element of the circuit IGEN_0 without disturbing all of the others. As a result, any modification results in complete re-dimensioning of the circuit IGEN_0, which makes the circuit difficult to configure and adapt, for example, to suit the application made thereof.

This type of circuit IGEN_0 also requires an initial start-up current Istrtup_0 generated by an ancillary circuit, which is inherently disadvantageous.

This type of circuit can also be subjected to a hump effect, which is roughly equivalent to a parasitic transistor effect under certain conditions. The hump effect can amplify the negative feedback on the output signal Iout_0, reducing the output signal to below a minimum operating value and causing the circuit to restart with the initial start-up current Istrtup_0, which has a cyclic pumping appearance PMP. For more information on the hump effect, a person skilled in the art can refer to the publication: Y. Joly et al, “Impact of hump effect on MOSFET mismatch in the sub-threshold area for low power analog applications,” 2010 10th IEEE International Conference on Solid-State and Integrated Circuit Technology, 2010, pp. 1817-1819, doi: 10.1109/ICSICT.2010.5667684.

There is thus a need to propose current sources whose intensity is modulated by an input signal, in particular within a feedback loop of a controlled system, that do not suffer from the aforementioned drawbacks.

### BRIEF SUMMARY

In this respect and according to one aspect, the present disclosure proposes an integrated circuit comprising a current source configured to generate a control current whose intensity is modulated by an input signal, wherein the current source includes a first stage configured to autonomously generate a constant component of the control current, and a second stage configured to autonomously generate a control current component that is modulated by the input signal.

Thus, unlike conventional architectures of the self-regulating β-multiplier type with an attenuation loop (FIG. 1), the generation of the constant current and the generation of the modulated feedback current are completely decorrelated. The two components of the control current can thus be easily trimmed and configured with great flexibility, advantageously speeding up the design cycles, allowing the circuit to be easily adapted to a modification or update affecting ancillary circuits working with the current source, and facilitating the trimming phases in industrial production.

Thus, for example and in particular, the DC component of the control current can be dimensioned so as to cancel out or prevent the hump effect or cyclic pumping effect, irrespective of the feedback design. Reciprocally, the modulated component can also be trimmed independently of the DC component. It should be noted that the hump effect may or may not occur randomly on given materialisations of the same integrated circuit.

According to one embodiment, the current source includes a reference generator circuit configured to generate a reference current, the first stage includes a first current mirror assembly powered by the reference current, with the second stage including a second current mirror assembly powered by the reference current.

This is a simple and effective solution that has all of the advantages mentioned hereinabove. For example, the reference generation circuit can be a self-biased reference circuit.

According to one embodiment, the second stage includes a converter circuit configured to generate a modulation current having an intensity that varies as a function of the input signal, and to inject or extract the modulation current into or from the reference current powering the second current mirror assembly.

Again, this makes the modulation function for the modulated component easy to adapt to the control current generation principle. More specifically, the converter circuit can be adapted to a desired modulation function, for example a linear function, or a square step, or a parabolic function, or any other mathematical transformation.

According to one embodiment, the second stage is configured to generate the modulated component proportional to the average value of the amplitude of an AC signal as an input signal.

According to one embodiment, the integrated circuit includes a system controlled by a control loop, for example a feedback loop, the control loop comprising said current source, the control current controlling an output signal of the system.

According to one embodiment, the system includes a crystal oscillator configured to generate an AC output signal of the system, the output signal of the system being the AC input signal of the control loop.

According to another aspect, the present disclosure proposes a method for generating a control current whose intensity is modulated by an input signal, wherein the generation of the control current includes a first autonomous generation of a constant component of the control current, and a second autonomous generation of a control current component that is modulated by the input signal.

According to one implementation, the generation of the control current includes generating a reference current powering said first autonomous generation and said second autonomous generation.

According to one implementation, the second autonomous generation of the modulated component of the control current includes generating a modulation current whose intensity varies as a function of the input signal, and injecting or extracting the modulation current into or from the reference current powering said second generation.

According to one implementation, the modulated component is proportional to the average value of the amplitude of an AC input signal.

According to one implementation, the method includes controlling a system by a control loop, the control loop comprising said generation of the control current, the control current controlling an output signal of the system.

According to one implementation, the AC output signal of the system is generated by a crystal oscillator, the output signal of the system being the AC input signal of the control loop.

### BRIEF DESCRIPTION OF DRAWINGS

Other advantages and features of the present disclosure will become apparent upon examining the detailed description of non-limiting embodiments and implementations, and from the accompanying drawings, in which figures:

FIG. 1, described hereinabove, illustrates a classic example of a current generator circuit;

FIG. 2, FIG. 3, and FIG. 4 illustrate embodiments and implementations of the present disclosure.

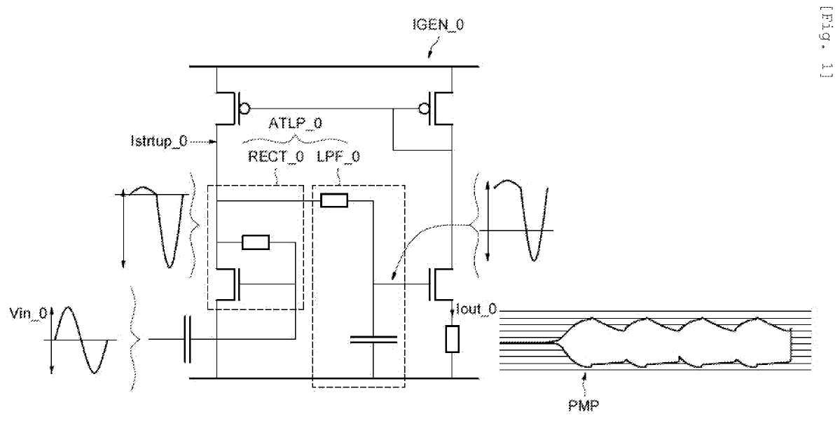

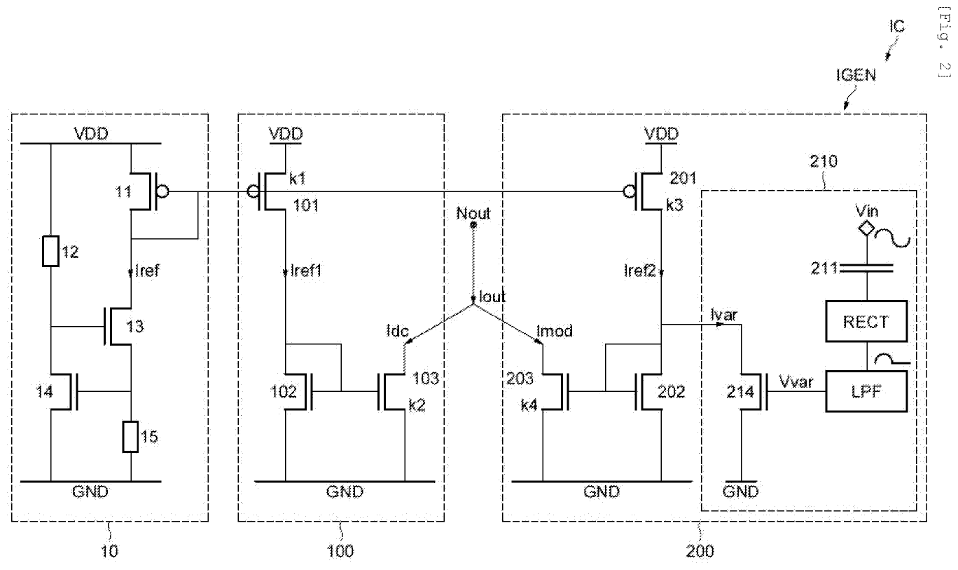

### DETAILED DESCRIPTION

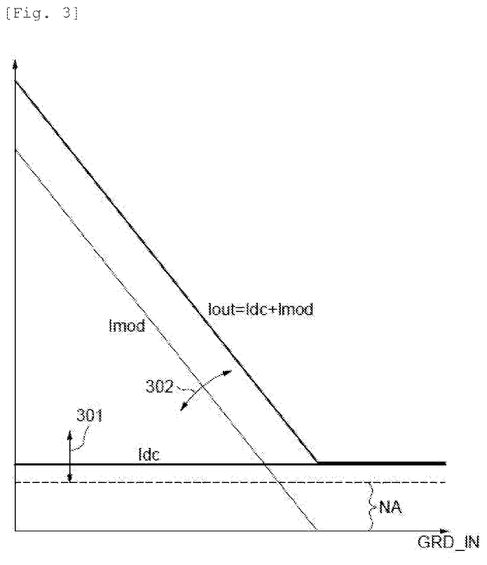

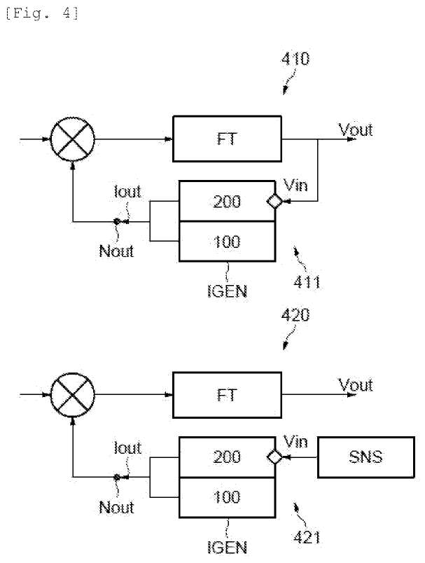

FIG. 2 illustrates an example of a circuit of a current source IGEN, typically integrated in an integrated circuit IC. For example, the current source can be intended to belong to a control or feedback loop of a controlled system (see FIG. 4 hereinbelow), in order to generate a control current Iout controlling an output signal Vout of the system.

The current source IGEN is configured to generate a control current Iout whose intensity is modulated by an input signal Vin.

The input signal Vin is obtained, for example, from the output signal Vout.

The current source IGEN includes a first stage 100 configured to autonomously generate a constant component Idc of the control current Iout, and a second stage 200 configured to autonomously generate a modulated component Imod of the control current Iout. The modulated component Imod is modulated by the input signal Vin, in other words, the modulated component Imod is generated as a function of the input signal Vin.

In this example, the current source IGEN includes a reference generator circuit 10 configured to generate a constant reference current Iref, for example a circuit of the self-biased reference type. The first stage 100 includes a first current mirror assembly 102, 103 powered by the reference current, or by a first copy Iref1 of the reference current Iref. The second stage 200 includes a second current mirror assembly 202, 203 powered by the reference current, or by a second copy Iref2 of the reference current Iref.

Moreover, in this example, in order to generate the modulated component Imod as a function of the input signal Vin, the second stage 200 includes a converter circuit 210 configured to generate a modulation current Ivar whose intensity varies as a function of the input signal Vin. The modulation current Ivar is injected into or extracted from the reference current Iref2 powering the second current mirror assembly.

According to a basic, practical example, as shown in FIG. 2, the reference generation circuit 10 of the self-biased reference type includes a diode-connected PMOS transistor 11 whose source is coupled to a supply voltage terminal VDD, a resistive element 12 coupled to the terminal VDD, an NMOS transistor 13 whose drain is coupled to the cathode (drain-gate node) of the diode-connected PMOS transistor 11, and whose gate is coupled to the resistive element 12 and to the drain of another NMOS transistor 14. The gate of this other transistor 14 is coupled to the source of the NMOS transistor 13, and its source is coupled to a ground reference voltage terminal GND. A load 15 is coupled between the source of the NMOS transistor 13 and the ground GND.

The reference current Iref generated on the drain of the diode-connected PMOS transistor 11 is thus constant and in particular does not vary according to fluctuations in the supply voltage VDD.

The first stage 100 includes a first copy PMOS transistor 101 whose gate is controlled by the voltage of the cathode (gate-drain node) of the diode-connected PMOS transistor 11 (i.e. the threshold voltage), so as to generate a first copy Iref1 of the reference current Iref, referred to herein as the first copy current Iref1. The intensity of the first copy current Iref1 can be equal to a factor k1 of the reference current Iref or equal to the reference current Iref (k1=1).

In the first stage 100, the first current mirror assembly includes a diode-connected NMOS transistor 102, coupled between the drain of the first copy PMOS transistor 101 and the ground GND, and a copy NMOS transistor 103 controlled by the voltage of the cathode (gate-drain node) of the diode-connected NMOS transistor 102 (i.e. the threshold voltage), and whose drain is coupled to an output node Nout and whose source is coupled to the ground GND.

The first current mirror assembly 102, 103 is thus powered by the first copy current Iref1 and generates a first output current Idc at the output node Nout. The intensity of the first output current Idc can be equal to a factor k2 of the first copy current Iref1 or equal to the first copy current Iref (k2=1). A constant current Idc that is proportional or equal to the reference current Iref has thus been generated, which current is included in the control current Iout as a constant component Idc.

The second stage 200 includes a second copy PMOS transistor 201 whose gate is controlled by the cathode voltage (gate-drain node) of the diode-connected PMOS transistor 11 (i.e. the threshold voltage), so as to generate a second copy Iref2 of the reference current Iref, referred to herein as the second copy current Iref2. The intensity of the second copy current Iref2 can be equal to a factor k3 of the reference current Iref or equal to the reference current Iref (k3=1).

In the second stage 200, the second current mirror assembly includes a diode-connected NMOS transistor 202, coupled between the drain of the second copy PMOS transistor 201 and the ground GND, and a copy NMOS transistor 203 controlled by the cathode voltage (gate-drain node) of the diode-connected NMOS transistor 202 (i.e. the threshold voltage), and whose drain is coupled to the output node Nout and whose source is coupled to the ground GND.

The second current mirror assembly 202, 203 is thus powered by the second copy current Iref2 and generates a second output current Imod at the output node Nout. The intensity of the second output current Imod can be equal to a factor k4 of the current flowing in the diode-connected NMOS transistor 202 of the second stage 200.

However, the modulation current Ivar has been injected into or extracted from (depending on the sign of the generation of the modulation current Ivar by the input converter 210) the second copy current Iref2 powering the second current mirror assembly 202, 203, i.e. the current flowing in the diode-connected NMOS transistor 202 of the second stage 200.

A current Imod that supports variations generated as a function of the input signal Vin, and that is included in the control current Iout as a modulated component Imod, has thus been generated.

It may be preferable to extract the modulation current Ivar with the same sign (positive or negative) as the sign of the second copy current Iref2 (or to inject the modulation current Ivar with the opposite sign to the sign of the second copy current Iref2). In other words, it may be preferable for the current resulting from the extraction/injection to have an absolute value that is lower than the second copy current Iref2, i.e.: |Iref2−Ivar|≤|Iref2|. This ensures that the modulated component Imod does not incorporate its own constant component.

For example, a modulation NMOS transistor 214 coupled between the ground GND and the anode (drain-gate node) of the transistor 202, and controlled by a modulation control signal Vvar, can enable such an extraction of the current Ivar with a positive sign from the second copy current Iref2 with a positive sign.

Finally, in this example, the input converter 210 is adapted to generate the modulation current Ivar corresponding to the average value of the amplitude of the AC input signal Vin; such that the modulated component Imod is inversely proportional to said average value of the amplitude of the AC input signal Vin (in particular according to the intensity of the modulation current Ivar and the factors k3, k4).

In this respect, the input converter 210 can include a rectifier or clipper circuit RECT receiving the input signal Vin, typically via a capacitive element 211 removing an offset, followed by a low-pass filter circuit LPF supplying the modulation control signal Vvar.

The control current Iout on the output node Nout thus results from the sum of the currents flowing on the output node, i.e. the sum of the DC component Idc generated by the first stage 100 and of the modulated component Imod generated by the second stage 200.

In this respect, reference is made to FIG. 3.

FIG. 3 illustrates, in the form of a graph, the method for generating the control current Iout=Idc+Imod, the intensity whereof is modulated by the input signal Vin (FIG. 2), including a first autonomous generation of the constant component Idc0 of the control current Iout, and a second autonomous generation of the modulated component Imod of the control current, the modulated component Imod being modulated by the input signal.

The control current Iout is obtained, for example, by the sum of the DC component Idc and of the modulated component Imod flowing on the output node Nout (FIG. 2).

Since the first generation by the first stage 100 and the second generation by the second stage 200 autonomously and independently generate the constant component Idc0 and the modulated component Imod respectively, the two components Idc, Imod of the control current Iout can be easily trimmed and configured 301, 302 with great flexibility.

In the case in FIG. 3, the modulated component is proportional to an input variable GRD_IN, and the trimming 302 can, for example, correspond to the coefficient of proportionality, i.e. the inclination of the slope.

The DC component Idc can, for example, be trimmed 301 to a level above a limit NA, such that the control signal Iout always remains above this limit value NA.

The constant current Idc can thus be dimensioned 301 to avoid specific bias points NA, for example to avoid breaking the bias of the whole circuit and to avoid undesirable non-linear behaviour of the circuit (which is one possible cause of a cyclic pumping effect). The constant current Idc can also be intended to avoid certain specific bias zones, such as bias zones that can lead to a hump effect.

Moreover, the converter circuit 210 can also be adapted to a desired modulation function, for example a linear function as represented Imod, or a square step, or a parabolic function, or any other mathematical transformation.

The architecture described with reference to FIG. 2 further allows for returning to a starting bias point when all of the stimuli are deactivated, without having to generate a reset signal.

FIG. 4 illustrates two examples of systems 410, 420 controlled by a control loop 411, 421, and including means FT provided to generate an output signal Vout.

For example, each controlled system 410, 420 can be produced such that it is integrated into the integrated circuit IC described hereinabove with reference to FIG. 2. The control loop comprises the current source IGEN as described hereinabove with reference to FIGS. 2 and 3, such that the control current Iout is used to control the generation of the output signal Vout of the system.

In the first example of a controlled system 410, the control loop 411 is of the “closed feedback loop” type and uses the output Vout of the system to regulate its own generation.

In this case, the system 410 can, for example, include a crystal oscillator FT configured to generate an output signal Vout of the system, which output signal is of the AC clock signal type. The AC output signal Vout of the system is thus used as the AC input signal Vin of the control loop 411, and thus of the current source IGEN as described hereinabove with reference to FIG. 2.

In the second example of a controlled system 420, the control loop 421 is of the “open configuration loop” type and is used to regulate the output Vout of the system as a function of an external parameter, such as a measurement made by a sensor SNS.

More specifically, the modulation criterion in the application of a crystal oscillator is typically the amplitude of the oscillation, whereas other applications can be based on other modulation criteria such as temperature, supply voltage, or other criteria. The decorrelation of the two stages 100, 200 of the current generator IGEN allows the feedback functionality to be freely and easily adapted to eliminate any design instabilities (for example a pumping effect).

Finally, the invention is not limited to the embodiments and implementations described hereinabove, but encompasses all alternative embodiments and implementations, for example, as mentioned hereinabove, the signs of the bias voltages and/or currents can be inverted, the modulation function can be defined differently, and other types of circuit can be considered, in particular for the reference generator circuit.

1. An integrated circuit comprising a current source configured to generate a control current whose intensity is modulated by an input signal, wherein the current source includes a first stage configured to autonomously generate a constant component of the control current and a second stage configured to autonomously generate a control current component that is modulated by the input signal.

2. The integrated circuit of claim 1, wherein the current source includes a reference generator circuit configured to generate a reference current, the first stage includes a first current mirror assembly powered by the reference current, and the second stage includes a second current mirror assembly powered by the reference current.

3. The integrated circuit of claim 2, wherein the second stage includes a converter circuit configured to generate a modulation current having an intensity that varies as a function of the input signal and to inject or extract the modulation current into or from the reference current powering the second current mirror assembly.

4. The integrated circuit of claim 1, wherein the second stage is configured to generate the control current component that is modulated proportional to an average value of an amplitude of an AC signal as the input signal.

5. The integrated circuit of claim 1 further comprising a system controlled by a control loop, wherein the control loop comprises said current source, and the control current is configured for controlling an output signal of the system.

6. The integrated circuit of claim 5, wherein the system includes a crystal oscillator configured to generate an AC output signal of the system, wherein the AC output signal of the system is the AC input signal of the control loop.

7. A method comprising:
generating a control current whose intensity is modulated by an input signal, wherein generating the control current includes a first autonomous generation of a constant component of the control current and a second autonomous generation of a control current component that is modulated by the input signal.

8. The method of claim 7, wherein generating the control current includes generating a reference current powering said first autonomous generation and said second autonomous generation.

9. The method of claim 8, wherein the second autonomous generation of the control current component that is modulated includes generating a modulation current whose intensity varies as a function of the input signal and injecting or extracting the modulation current into or from the reference current powering said second generation.

10. The method of claim 7, wherein the control current component that is modulated is proportional to an average value of an amplitude of an AC input signal.

11. The method of claim 7 further comprising:
controlling a system by a control loop, wherein the control loop comprises generating the control current; and
controlling an output signal of the system with the control current.

12. The method of claim 11 further comprising:
generating an AC output signal of the system by a crystal oscillator, wherein the AC output signal of the system is the AC input signal of the control loop.
